(19) United States
(12) Patent Application Publication
(10) Pub. No.: US 2007/0161232 A1
(43) Pub. Date: Jul. 12, 2007

(54) METHOD FOR FORMING METAL INTERCONNECTION IN SEMICONDUTOR DAMASCENE PROCESS

(76) Inventor: Se Yeul Bae, Gyeonggi-do (KR)

Correspondence Address: SHERR & NOURSE, PLLC, 620 HERNDON PARKWAY, SUITE 200, HERNDON, VA, 20170, US

(21) Appl. No.: 11/616,273

(22) Filed: Dec. 26, 2006

(30) Foreign Application Priority Data
Dec. 27, 2005 (KR) 10-2005-0131009

(51) Int. Cl. H01L 21/4763

(52) U.S. Cl. 438/638; 257/E21.579

(57) ABSTRACT

A method for forming metal interconnections in a semiconductor damascene process, in which a selective deposition of an etch stop layer formed above a lower metal interconnection by the damascene process prevents an etch attack against the lower metal interconnection. The method includes forming a first conductive layer over a semiconductor substrate.

The present application claims priority under 35 U.S.C. 119 and 35 U.S.C. 365 to Korean Patent Application No. 10-2005-0131009 (filed on Dec. 27, 2005), which is hereby incorporated by reference in its entirety.

### BACKGROUND

In general, as the semiconductor industry moves to very large scale integration (VLSI), the geometrical dimensions of devices continue to be reduced to the sub-half-micron region, circuit density is increasing, and performance and reliability are improving.

In response to a demand for even larger scale integration, a copper (Cu) thin film may be used as an interconnection material, because copper has a melting point higher than that of aluminum (Al) which results in high resistance against electro-migration (EM), copper can improve reliability in semiconductor devices. Because copper has a low resistivity, it can also increase signal transfer speeds.

With high-density integration and technical development of semiconductor devices, parasitic capacitance between the interconnections is emerging as a problem. If the parasitic capacitance is high, the semiconductor device is subjected to a higher RC delay, increase in power consumption, and noise caused by interference. These effects serve as obstacles to high-speed operation. Therefore, a dielectric material, such as a porous oxide, having a low dielectric constant (or a low-k) of 3 or less is used as an interlayer insulating material.

In the interconnection process using copper and the low-k dielectric material, it is very difficult to properly etch copper. To solve this problem, a dual damascene process may be applied.

The dual damascene process may be used in 0.13 μm technology or less, and can be divided into four processes: a buried-via process, a via-first process, a trench-first process, and a self-aligned process.

The speed of a complementary metal oxide semiconductor (CMOS) logic device is increased by decreasing the gate delay with a shorter gate path. However, the speed of CMOS logic is also affected by RC delays in back-end-of-line (BEOL) metallization due to high density integration and parasitic capacitance.

In order to reduce this RC delay, a low resistivity metal such as copper and a low-k dielectric material for the interlayer insulating material is applied in a dual damascene process.

FIGS. 1A through 1H are sectional views of a semiconductor device, for explaining a related method for forming a dual damascene pattern.

Referring to FIG. 1A, a first insulating layer (not shown), and a first conductive layer 100, i.e. a lower metal layer to which copper including a barrier metal is applied, are formed on a semiconductor substrate 10 in which devices such as transistors are already formed. An etch stop layer 102 and a second insulating layer 104 are stacked over the first conductive layer 100. The second insulating layer 104 may be formed of fluorosilicate glass (FSG) or P—SiH4 oxide.

The etch stop layer 102 limits the etching depth in subsequent processes of forming a contact between metal interconnections. In particular, the etch stop layer 102 prevents an etchant from attacking the lower metal layer when layer 104 is etched to form a via or contact. The etch stop layer 102 also prevents hole filling and voids in the metal interconnection. The etch stop layer 102 may be used as an anti-diffusion layer or a capping layer, preventing copper from being diffused from a copper interconnection to the surrounding non-metal layers.

However, the etch stop layer or the anti-diffusion layer applied over the copper metal interconnection and the interlayer insulating layer may increase the effective dielectric constant k of the interlayer insulating layer, and increase parasitic capacitance. Hence, the RC delay is increased, and the operating speed of the semiconductor device is lowered.

In FIG. 1B, a first photoresist (not shown) pattern for a via hole is formed over second insulating layer 104 of FIG. 1A using a photolithographic process. The second insulating layer 104 is etched using the photoresist pattern for the via hole as a mask, forming a via hole 106. A reference numeral 104a indicates the etched second insulating layer. As illustrated, the depth of the via hole etch is limited by the etch stop layer 102.

In FIG. 1C, the photoresist pattern for the via hole formed in FIG. 1B is removed, and a sacrificial layer 108 is applied and recessed from plane of the upper surface of layer 104a. The sacrificial layer 108 remains only in the via hole.

The sacrificial layer 108 is simultaneously removed when a subsequent photoresist pattern for forming a trench is removed, and is used for preventing an attack on the etch stop layer 102. Specifically, when the trench for the metal connection is formed, the etch stop layer exposed at the bottom of the via hole would be removed if the sacrificial layer 108 were absent. The metal interconnection would be attacked and undergo undesirable changes in EM characteristics, resistance, formation of voids, etc. For this reason, the sacrificial layer 108 is placed in via hole 106, a layer which is easily removable, before etching the trench.

In FIG. 1D, a second photoresist (not shown) for forming the trench is deposited over the substrate, and patterned by a photolithographic process to form a second photoresist pattern 110. The second insulating layer 104a is etched using the second photoresist pattern 110 as a mask, thereby forming a trench interconnection region. Reference numeral 104b indicates the etched second insulating layer.

The sacrificial layer 108 remains in the via hole region 106, and thus prevents the attack of the etch stop layer under the via hole when the trench is formed.

In FIG. 1E, the second photoresist pattern 110 is removed. The sacrificial layer 108 remaining in the via hole region 106 is removed at the same time. However, a polymer generated during the formation of the trench remains on the sacrificial layer 108, and obstructs the concurrent removal of the sacrificial layer 108 and the second photoresist pattern 110 when the trench is removed. As a result, the sacrificial layer 108 may remain in the via hole region 106. In this case, the contact is not fully exposed. In order to prevent this effect, a post etch treatment for removing the polymer must be performed after forming the trench. The total processing time and expense is therefore increased.

In FIG. 1F, the etch stop layer under the via hole is blanket-etched, without use of a mask pattern, and removed. The lower metal interconnection is thereby exposed.

In FIG. 1G, a second conductive layer 112, i.e., an upper metal layer is deposited over the structure, filling inner portions of the via hole and the trench. The second conductive layer 112 may be formed of copper including a barrier metal as described above. Before the second conductive layer 112 is formed, a barrier metal layer or anti-diffusion layer for preventing copper from laterally diffusing can be formed. After the second conductive layer 112 is deposited, a chemical mechanical polishing process is performed, so that the second conductive layer 112 remains only in the via hole and the trench. A via contact and an interconnection are thereby formed.

FIG. 1H illustrates a metal interconnection having a plurality of layers, for instance five layers, made by repeating the method described above for a series of metal interconnections. A first etch stop layer 102, a second etch stop layer 102′, a third etch stop layer 102″, and a fourth etch stop layer 102′″ are used between every two metal interconnections in order to prevent copper diffusion.

These etch stop layers increase the dielectric constant k of the interlayer insulating layer, and the resulting parasitic capacitance, as described above. RC delays are increased, lowering the operating speed of the device.

### SUMMARY

Embodiments relate to a method for forming a fuse region in a semiconductor damascene process, suitable to suppress surface migration of copper and prevent increase of resistance-capacitance (RC) delays caused by a capping layer.

Embodiments relate to a method for forming a metal interconnections in a semiconductor damascene process, in which a selective deposition of an etch stop layer formed above a lower metal interconnection by the damascene process prevents an etch attack against the lower metal interconnection to improve characteristics of a semiconductor device.

Embodiments relate to a method for forming a metal interconnection in a semiconductor damascene process. The method includes forming a first conductive layer over a semiconductor substrate. A selective deposition layer is selectively deposited over the first conductive layer. An interlayer insulating layer is formed over the selective deposition layer and the first conductive layer. A photoresist is deposited over the interlayer insulating layer and forming a photoresist pattern for a via hole by using a photolithographic process.

A first etching process is performed on the interlayer insulating layer using the photoresist pattern for the via hole as a mask, thereby forming a via hole. The photoresist pattern for the via hole is removed. A second photoresist is applied over the interlayer insulating layer, and then a second photoresist pattern for forming a trench is formed. A second etching process is performed on the interlayer insulating layer using the second photoresist pattern for forming the trench as a mask, and thereby forming a trench.

The photoresist pattern for forming the trench is removed. A second conductive layer is deposited over the interlayer insulating layer, filling the via hole and the trench. The second conductive layer is then polished to complete the metal interconnection.

The selective deposition layer is used as an etch stop layer when the via hole is formed. The selective deposition layer is used as an anti-diffusion layer for preventing a metal from being diffused upward from the first conductive layer. The selective deposition layer may be deposited to overhang the first conductive layer. The selective deposition layer is formed of one of W, Ti, TiN, Ta, and TaN. The first conductive layer and the second conductive layer may include copper.

A second metal interconnection may be formed by repeating the above method where the completed metal interconnection serves as the first conductive layer over a semiconductor substrate in a repetition of the method. Additional metal interconnections may be formed in the same way.

The interlayer insulating layer may have a low-k dielectric material having a dielectric constant of 3.0 or less such as fluorosilicate glass (FSG) or SiO2.

### BRIEF DESCRIPTION OF DRAWINGS

FIGS. 1A through 1H are sectional views, of a semiconductor device, for explaining a related method for forming a dual damascene pattern; and

FIGS. 2A through 2F are sectional views of a semiconductor device, for explaining a method for forming a metal interconnection in a semiconductor damascene process in accordance with embodiments.

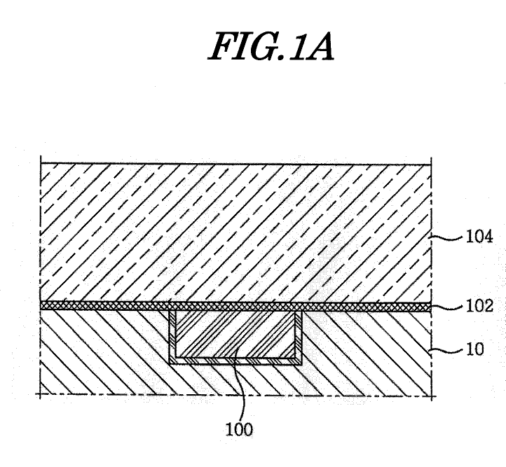

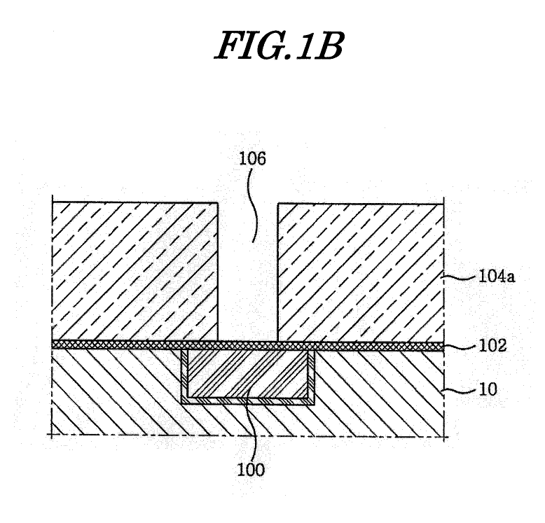

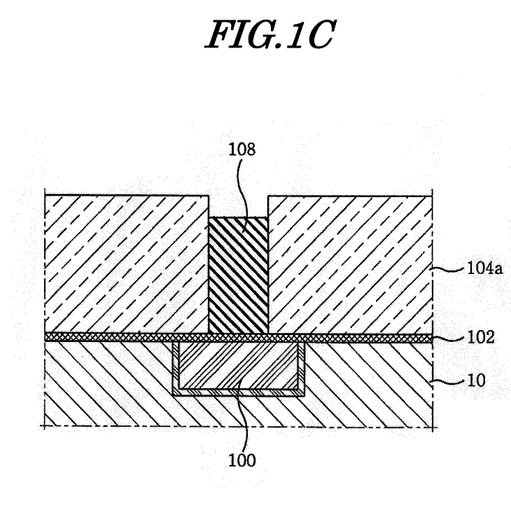

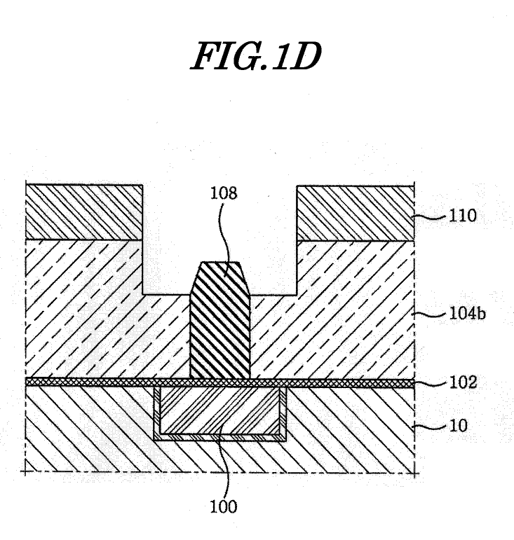

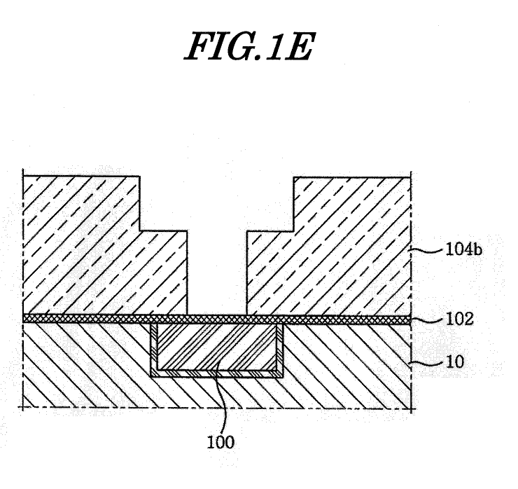

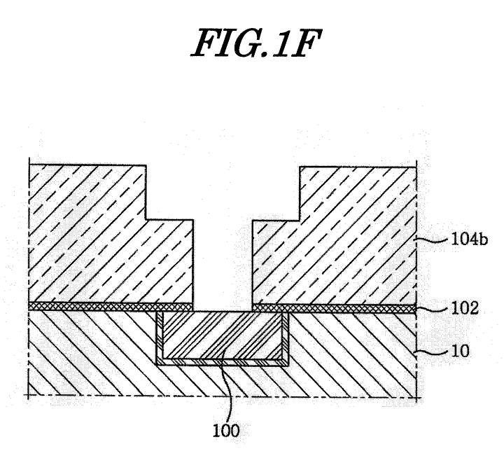

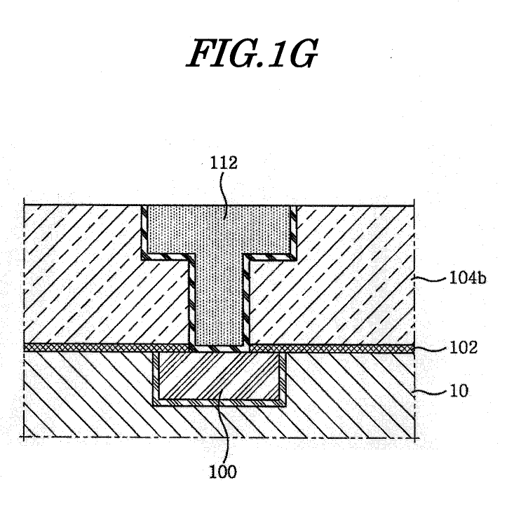

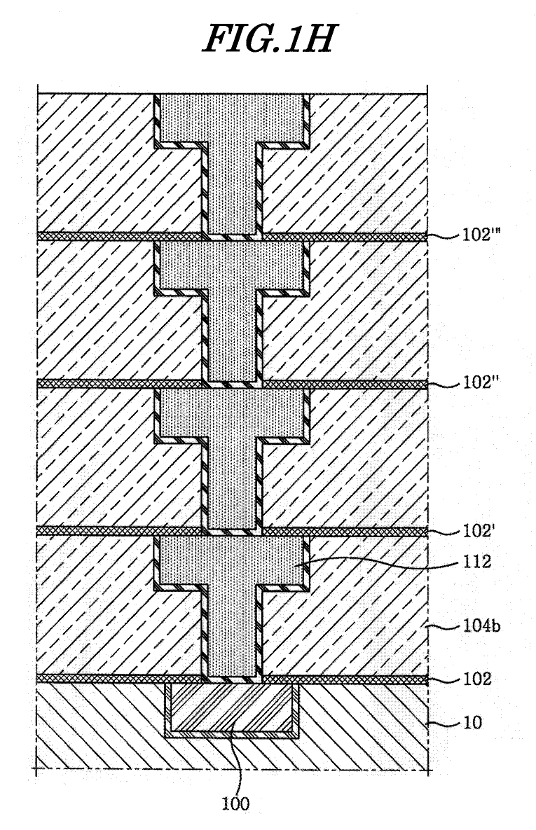

### DETAILED DESCRIPTION

Previous to the description, the subject matter of the embodiments is directed to forming a selective deposition layer, such as of W, Ti, TiN, Ta, TaN, etc., instead of an etch stop layer, such as of nitride in the related art, over a lower metal interconnection, and thereby prevent copper from being diffused outside the metal interconnection without increasing a dielectric constant. The aims of the embodiments can be easily accomplished from this technical viewpoint.

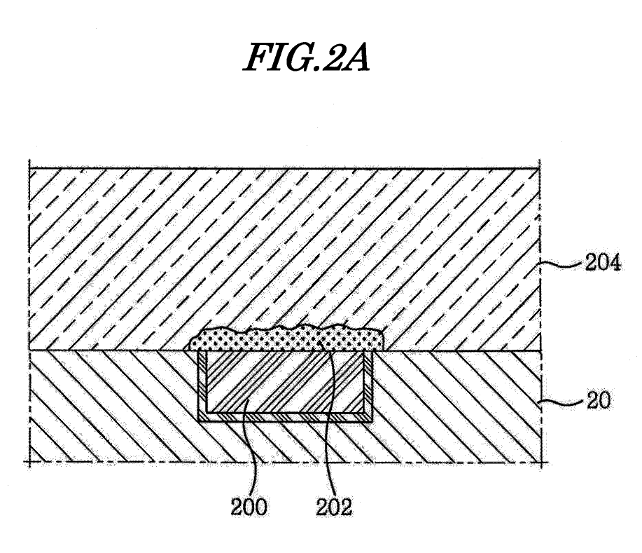

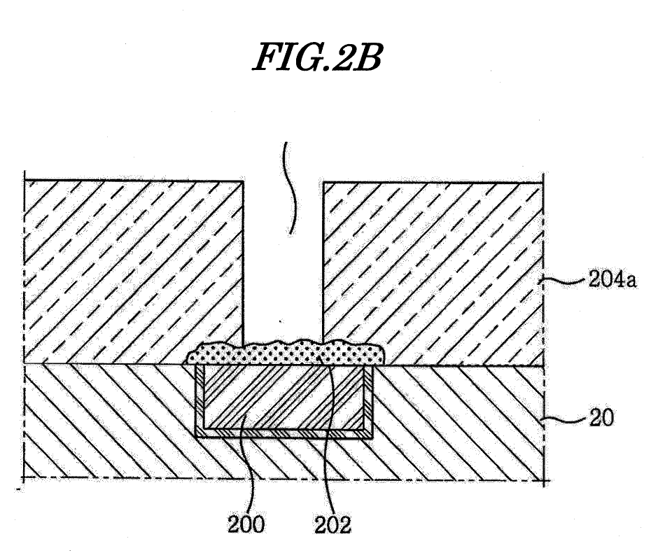

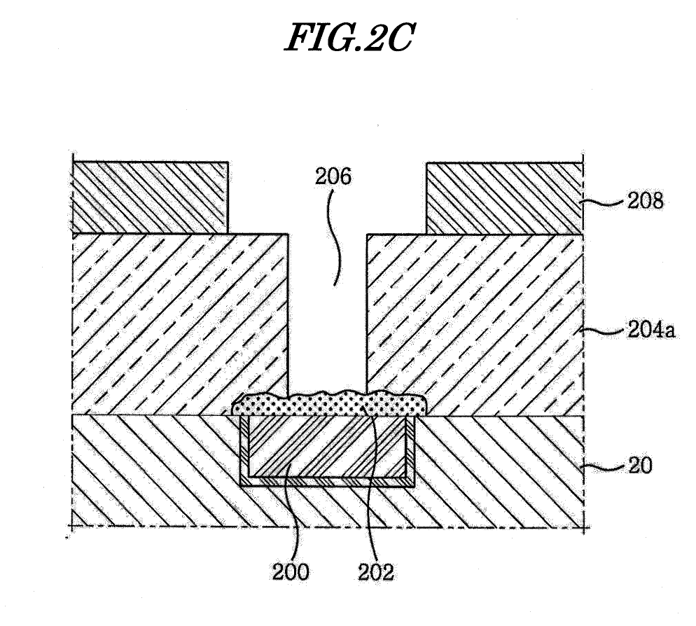

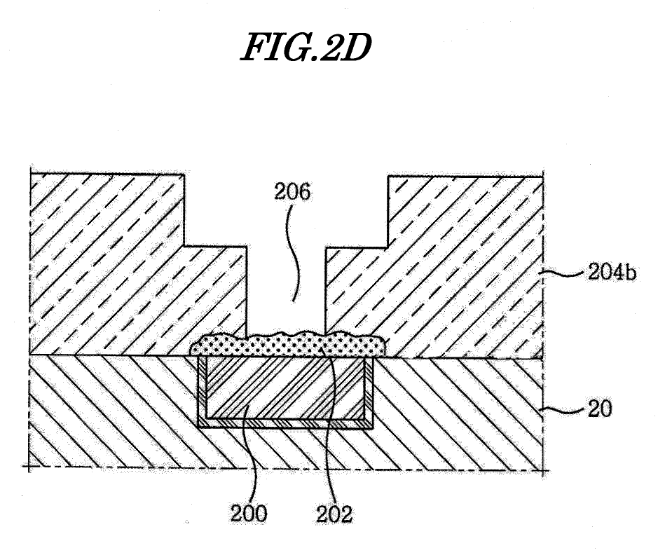

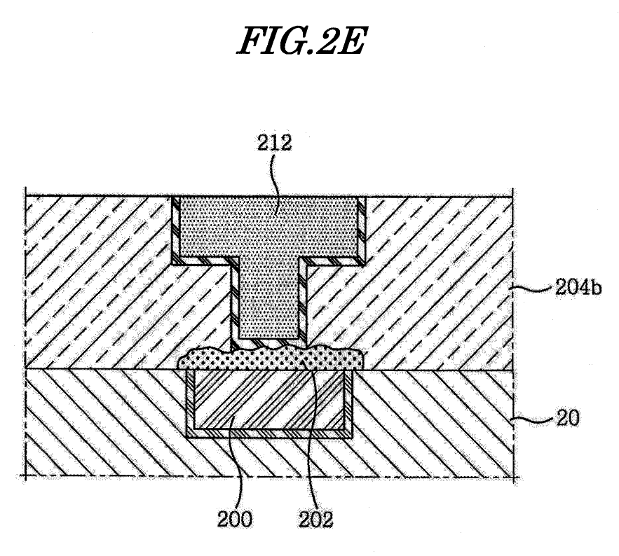

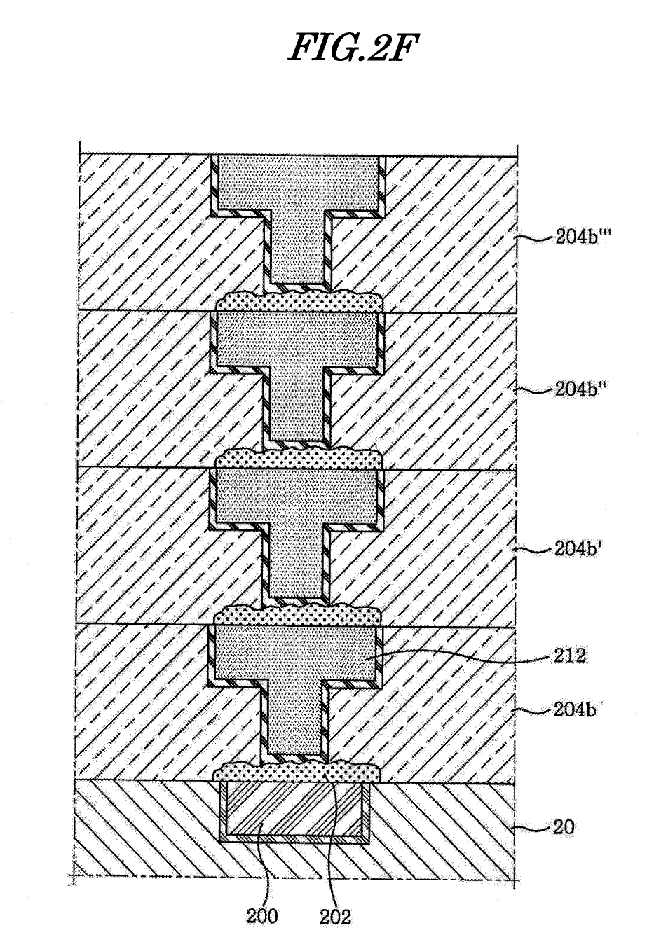

FIGS. 2A through 2F are sectional views of a semiconductor device, for explaining a method for forming a metal interconnection in a semiconductor damascene process in accordance with embodiments.

Referring to FIG. 2A, a first insulating layer (not shown), and a first conductive layer 200, i.e. a lower metal layer to which copper including a barrier metal is applied, are formed over a semiconductor substrate 20. Semiconductor devices such as transistors are present in the semiconductor substrate 20, and may be connected to conductive layer 200. A conductive layer is selectively deposited above the conductive layer 200, thereby forming a selective deposition layer 202. A second insulating layer 204 is deposited over the whole structure.

The selective deposition layer 202 is formed only above the first conductive layer 200 using selective deposition techniques. The selective deposition layer 202 may serve as an etch stop layer in subsequent processes. In comparison with the related art in which the etch stop layer, such as nitride, is etched, selective deposition layer 202 is not etched. Therefore, an attack caused by etching through the nitride to the lower metal interconnection can be completely removed. Electro-migration (EM) characteristics of the semiconductor device are improved. A void or gap-fill characteristic caused by the attack of the metal interconnection can be improved. The selective deposition layer 202 is used as an anti-diffusion layer or a capping layer for preventing copper from being diffused upward in the copper metal interconnection. The selective deposition layer is deposited only above the metal interconnection, thereby completely solving the problem relating to the increase of the dielectric constant, and increasing the operating speed of the semiconductor device.

The selective deposition layer 202 can by formed of any one of, for instance, W, Ti, TiN, Ta, and TaN. It may be deposited to overhang or extend past the conductive layer 200, as wide as possible without shorting adjacent elements or devices. This secures a margin for misalignment between a via hole and the lower metal interconnection in the subsequent processes.

The second insulating layer 204 may include a low-k insulating layer having a dielectric constant of 3.0, and may be formed of fluorosilicate glass (FSG) or SiO2.

In FIG. 2B, a first photoresist (not shown) is applied over the whole structure, and then a first photoresist pattern for the via hole is formed by a photolithographic process. The second insulating layer 204 is etched using the photoresist pattern for the via hole as a mask, thereby forming a via hole 206. A reference numeral 204a indicates the etched second insulating layer.

When the etch for forming the via between the metal interconnections is performed, the etch is stopped by the selective deposition layer 202. The selective deposition layer 202 serves as an etch stop layer for preventing the lower metal interconnection, particularly copper, from being eroded or attacked by the etch.

In FIG. 2C, the photoresist pattern for the via hole is removed, and a second photoresist, for forming a trench, is applied. A photolithographic process is performed on the second photoresist, thereby forming a second photoresist pattern 208. Then, the second insulating layer 204 is etched a second time using the second photoresist pattern 208 as a mask, thereby forming a trench. A reference numeral 204b indicates the etched second insulating layer.

The selective deposition layer 202 again functions as the etch stop layer, and thus prevents the lower metal interconnection from being attacked by etching the trench. As such, a sacrificial layer for preventing the lower metal interconnection from being exposed during trench formation as in the related art is not required.

In FIGS. 2D and 2E, the second photoresist pattern 208 is removed. A second conductive layer 212, i.e., an upper metal layer, is deposited over the whole structure, thereby filling the via hole and the trench. The second conductive layer 212 may be formed of copper, and may include a barrier metal layer as described above. When the second conductive layer 212 is filled, a chemical mechanical polishing (CMP) process is performed, so that the deposited second conductive layer 212 is planarized. In other words, the material from the second conductive layer 212 remains only in, and completely fills, the via hole and the trench. A via contact and an interconnection are thereby formed. Before the second conductive layer 212 is deposited, a barrier metal layer or an anti-diffusion layer for preventing copper from being diffused into other regions can be formed.

FIG. 2F illustrates a metal interconnection having a plurality of layers, for instance five layers, using the method for forming a series of metal interconnections in accordance with embodiments.

A second insulating layer 204b, a third insulating layer 204b′, a fourth insulating layer 204b″, and a fifth insulating layer 204b′″, all of which are used as the interlayer insulating layers, do not have the etch stop layer or the anti-diffusion layer (or the capping layer) that increases the dielectric constant k as in the related art, as illustrated in FIG. 2F. This avoids the problem of increased RC delays due to increased parasitic capacitance which thereby lowers the operating speed of the semiconductor device.

Although the embodiments are illustrative of the metal interconnection having a plurality of layers including the second, third, fourth, and fifth insulating layers 204b, 204b′, 204b″, and 204′″, this metal interconnection is merely illustrative but not essential to embodiments. For example, the number of interlayer insulating layers and the number of metal interconnection layers may be decreased or increased according to requirements.

As described above, in embodiments, the selective deposition layer is selectively deposited only above the lower metal interconnection, so an etch stop function is realized without increasing the dielectric constant k.

According to embodiments, the deposition layer is selectively formed only above the lower metal interconnection, so that it can effectively function as the anti-diffusion or the capping layer, preventing the dielectric constant from increasing. The embodiments prevent an attack against the lower metal interconnection, so that the process of forming the sacrificial layer in the via hole is not required, and thus the entire process is simplified.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed:

1. A method of forming a metal interconnection in a semiconductor damascene process comprising:
forming a first conductive layer over a semiconductor substrate;
selectively depositing a selective deposition layer over the first conductive layer;
forming an interlayer insulating layer over the selective deposition layer and the first conductive layer;
depositing a photoresist over the interlayer insulating layer and forming a photoresist pattern for a via hole by using a photolithographic process;
performing a first etching process on the interlayer insulating layer using the photoresist pattern for the via hole as a mask, thereby forming a via hole;
removing the photoresist pattern for the via hole;
applying a second photoresist over the interlayer insulating layer, and then forming a second photoresist pattern for forming a trench;
performing a second etching process on the interlayer insulating layer using the second photoresist pattern for forming the trench as a mask, and thereby forming a trench;
removing the photoresist pattern for forming the trench;
depositing a second conductive layer over the interlayer insulating layer, filling the via hole and the trench; and
polishing the second conductive layer to form a metal interconnection.

2. The method of claim 1, wherein the selective deposition layer is used as an etch stop layer when the via hole is formed.

3. The method of claim 1, wherein the selective deposition layer is used as an anti-diffusion layer for preventing a metal from being diffused upward from the first conductive layer.

4. The method of claim 1, wherein the selective deposition layer is used as a capping layer for preventing a metal from being diffused upward the first conductive layer.

5. The method of claim 1, wherein the selective deposition layer is deposited to overhang the first conductive layer.

6. The method of claim 1, wherein the selective deposition layer is formed of one of W, Ti, TiN, Ta, and TaN.

7. The method of claim 1, wherein the first conductive layer comprises copper.

8. The method of claim 1, wherein the second conductive layer comprises copper.

9. The method of claim 1, further comprising forming a second metal interconnection by repeating the method recited in claim 1, wherein the metal interconnection completed in claim 1 serves as said first conductive layer over a semiconductor substrate in a repetition of the method of claim 1.

10. The method of claim 9, further comprising forming a third and a fourth metal interconnection.

11. The method of claim 9, wherein the interlayer insulating layer comprises a low-k dielectric material having a dielectric constant of 3.0 or less.

12. The method of claim 11, wherein the low-k dielectric material comprises fluorosilicate glass (FSG).

13. The method of claim 11, wherein the low-k dielectric material comprises SiO2.

14. A method comprising:
forming a first conductive layer over a semiconductor substrate;
selectively depositing a selective deposition layer over the first conductive layer;
forming an interlayer insulating layer over the selective deposition layer and the first conductive layer;
etching the interlayer insulating layer to form a via hole;
etching the interlayer insulating layer to form a trench over the via hole;
depositing a second conductive layer over the interlayer insulating layer, filling the via hole and the trench; and
polishing the second conductive layer to form a metal interconnection.

15. The method of claim 14, wherein the selective deposition layer is used as an etch stop layer when the via hole is formed.

16. The method of claim 14, wherein the selective deposition layer is deposited to overhang the first conductive layer.

17. The method of claim 14, wherein the selective deposition layer is formed of one of W, Ti, TiN, Ta, and TaN.

18. The method of claim 14, wherein the first and second conductive layers comprise copper.

19. A semiconductor device comprising:
a first copper layer formed over a semiconductor substrate;
a conductive layer, comprising one of W, Ti, TiN, Ta, and TaN, selectively deposited over the first copper layer;
a low-K interlayer insulating layer over the conductive layer and the first copper layer;
a second copper layer filling a via hole and a trench in the interlayer insulating layer.

20. The device of claim 19, wherein the conductive layer overhangs a portion of the first copper layer.
